(19) United States
(12) Patent Application Publication
(10) Pub. No.: US 2010/0019977 A1
(43) Pub. Date: Jan. 28, 2010

(54) ANTENNA TEST APPARATUS

(75) Inventors: Chih-Wei Chang, Tao-Yuan Hsien (TW); Yun-Tung Chang, Tao-Yuan Hsien (TW)

Correspondence Address: PRO-TECHTOR INTERNATIONAL SERVICES, 20775 NORADA CT., SARATOGA, CA, 95070, US

(73) Assignee: AUDEN TECHNO CORPORATION, Tao-Yuan Hsien (TW)

(21) Appl. No.: 12/181,292

(22) Filed: Jul. 28, 2008

(51) Int. Cl. G01R 29/08

(52) U.S. Cl. 343/703

(57) ABSTRACT

In an antenna test apparatus of the type having a platform for carrying an antenna for test and a pressure board vertically movable by a lifter to hold down a test antenna in the platform for test, the platform has a top flange formed of an electromagnetic wave absorbing material and raised around the periphery, and the pressure board has a bottom flange formed of an electromagnetic wave absorbing material for stopping against the top flange of the platform to protect an antenna to be tested in between the platform and a bottom soft flange of the pressure board against external electromagnetic noises.

### BACKGROUND OF THE INVENTION

1. Field of the Invention

The present invention relates to antenna test equipment and more particularly, to an antenna test apparatus, which simplifies antenna test procedure and shortens antenna testing time.

2. Description of the Related Art

After fabrication of an antenna, the antenna must be examined through a simulation test before installation. FIG. 1 illustrates a conventional antenna test apparatus for testing antennas. As illustrated, the antenna test apparatus comprises a base 91, a platform 92 provided at the top side of the base 91 for supporting an antenna 9 to be tested in a horizontal position, an upright support 93 fixedly provided at the top side of the base 91 adjacent to the back side of the platform 92, a lifter 94 provided at the front side of the upright support 93, and a top pressure board 95 coupled to the lifter 94 in horizontal and vertically movable by the lifter 94 above the platform 92.

When testing an antenna, connect the power jack 911 at one lateral side of the base 91 to an electrical outlet with a power cable and then connect the signal line (coaxial cable) of the control computer (not shown) to the computer connector 913 at the base 91, and then switch on the power switch 912 at the base 91. Thereafter, put the antenna 9 to be tested on the platform 92 in a horizontal position, and then operated the control buttons 914 at the base 91 to drive the lifter 94 in lowering the top pressure board 95, causing the bottom soft sponge of the top pressure board 95 to be pressed on the antenna 9 against the platform 92 for starting the test procedure.

To avoid external interference, the antenna test apparatus must be kept in a shielding box during operation. Upon each test, the shielding box must be opened and closed. After loading one antenna to be tested in the antenna test apparatus, the position of the antenna test apparatus in the shielding box must be calibrated. This antenna test manner wastes much time. Therefore, an improvement in this regard is necessary.

### SUMMARY OF THE INVENTION

The present invention has been accomplished under the circumstances in view. It is one object of the present invention to provide an antenna test apparatus, which simplifies antenna test procedure and shortens antenna testing time.

To achieve this and other objects of the present invention, the antenna test apparatus comprises a base, a platform provided at the top side of the base for supporting an antenna for test, an upright support upwardly extending from the base and disposed adjacent to the back side of the platform, a top pressure board provided above the platform and having a soft sponge bonded to the bottom wall thereof, and a lifter provided at the front side of the upright support and controllable to move the top pressure board vertically relative to the platform. Further, the platform comprises a top flange formed of an electromagnetic wave absorbing material and raised around the periphery. The top pressure board comprises a bottom flange formed of an electromagnetic wave absorbing material and extending around the soft sponge for stopping against the top flange of the platform to protect the loaded antenna to be tested in between the platform and the soft flange against external electromagnetic noises.

### BRIEF DESCRIPTION OF THE DRAWINGS

FIG. 1 is an elevational view of an antenna test apparatus according to the prior art.

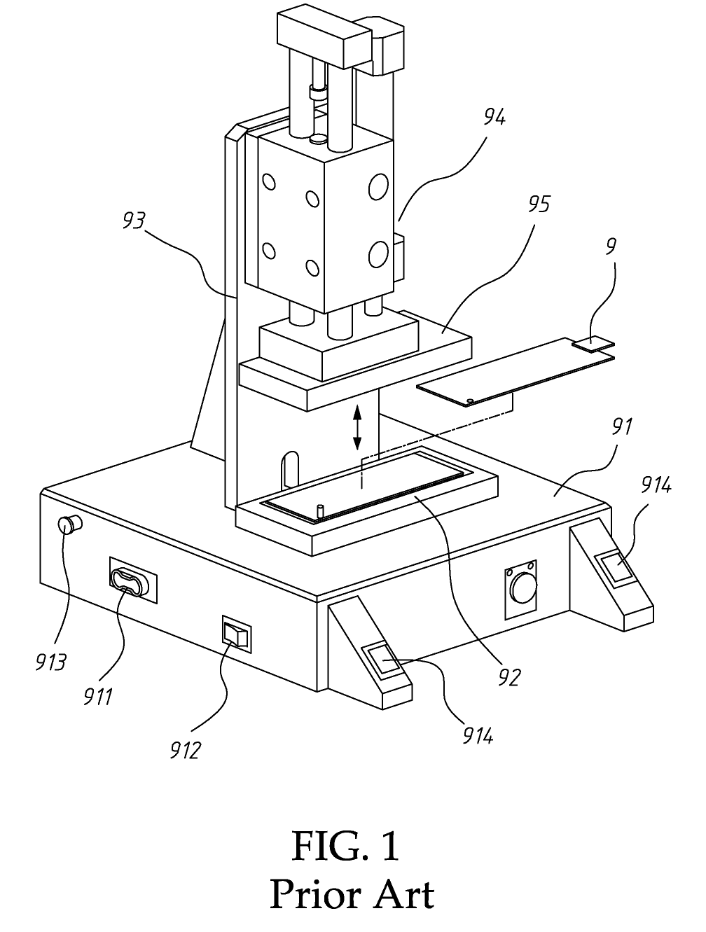

FIG. 2 is an elevational view of an antenna test apparatus in accordance with the present invention.

FIG. 3 is a sectional side view of the antenna test apparatus in accordance with the present invention.

### DETAILED DESCRIPTION OF THE PREFERRED EMBODIMENT

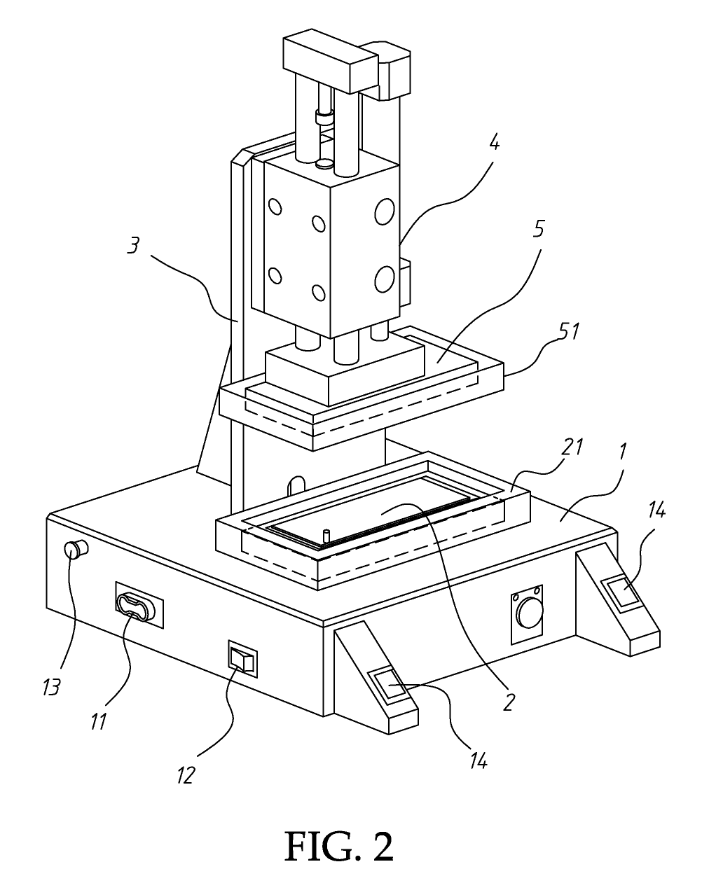

Referring to FIG. 2, an antenna test apparatus in accordance with the present invention is shown comprising a base 1, a platform 2 provided at the top side of the base 1 for supporting an antenna to be tested, an upright support 3 fixedly provided at the top side of the base 1 adjacent to the back side of the platform 2, a lifter 4 provided at the front side of the upright support 3, and a top pressure board 5 coupled to the lifter 4 in horizontal and vertically movable by the lifter 4 above the platform 2.

The base 1 is provided with a power jack 11 for connection to an external power source with a power cable, a computer connector 13 connectable to a computer (not shown) that controls the operation of the antenna test apparatus, a power switch 12 for power on/off control, and control buttons 14 for controlling the operation of the lifter 4 to lift/lower the top pressure board 5.

The platform 2 has a top flange 21 formed of an electromagnetic wave absorbing material and raised around the periphery thereof. Further, the top pressure board 5 has a soft sponge 52 bonded to the bottom wall and a bottom flange 51 formed of an electromagnetic wave absorbing material and downwardly protruded around the bottom wall around the soft sponge 52 corresponding to the top flange 21 of the platform 2.

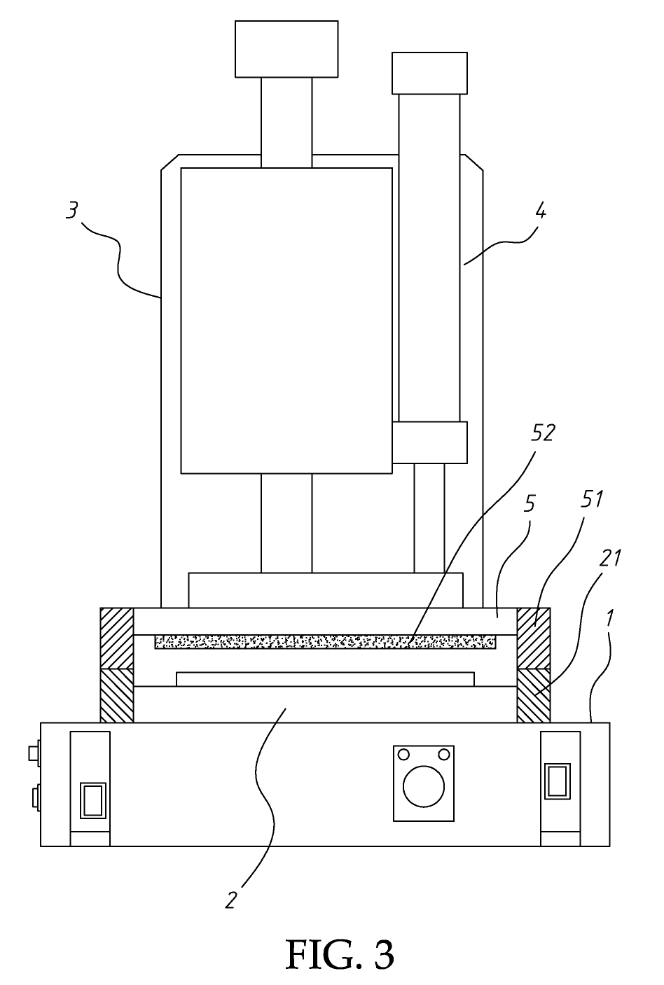

Referring to FIG. 3 and FIG. 2 again, after connection of the power jack 11 to an external power source with a power cable and loading of an antenna to be tested in the platform 2, the power switch 12 is switched on, and then the control buttons 14 are operated to drive the lifter 4, causing the lifter 4 to lower the top pressure board 5 and to force the soft sponge 52 of the top pressure board 5 against the test antenna in the platform 2. At this time, the bottom flange 51 of the top pressure board 5 is stopped against the top flange 21 of the platform 2 to shield the test antenna against external electromagnetic interference.

By means of the application of the present invention, the test antenna is well protected by the bottom flange 51 of the top pressure board 5 and the top flange 21 of the platform 2 to against external electromagnetic interference. Therefore, it is not necessary to put the antenna test apparatus in a shielding box during an antenna test operation. During an antenna test operation, the operator needs only to control the lifter 4 in lifting/lowering the top pressure board 5. Therefore, the invention greatly shortens each antenna testing time.

Although particular embodiments of the invention have been described in detail for purposes of illustration, various modifications and enhancements may be made without departing from the spirit and scope of the invention. Accordingly, the invention is not to be limited except as by the appended claims.

What the invention claimed is:

1. An antenna test apparatus, comprising:
a base;
a platform provided at a top side of said base for supporting an antenna for test;
an upright support upwardly extending from said base and disposed adjacent to a back side of said platform;
a top pressure board provided above said platform, said top pressure board comprising a soft sponge bonded to a bottom wall thereof; and
a lifter provided at a front side of said upright support and controllable to move said top pressure board vertically relative to said platform;
wherein said platform comprises a top flange formed of an electromagnetic wave absorbing material and raised around the periphery thereof; said top pressure board comprises a bottom flange formed of an electromagnetic wave absorbing material and extending around said soft sponge for stopping against said top flange of said platform to protect the loaded antenna to be tested in between said platform and said soft flange against external electromagnetic noises.
